(19) United States
(12) Patent Application Publication
(10) Pub. No.: US 2017/0330764 A1
(43) Pub. Date: Nov. 16, 2017

(54) METHODS AND APPARATUSES FOR CONTROLLING TRANSITIONS BETWEEN CONTINUOUS WAVE AND PULSING PLASMAS

(71) Applicant: Lam Research Corporation, Fremont, CA (US)

(72) Inventors: Canfeng Lai, Fremont, CA (US); Liang Meng, Sherwood, OR (US)

(73) Assignee: Lam Research Corporation, Fremont, CA (US)

(21) Appl. No.: 15/588,553

(22) Filed: May 5, 2017

Related U.S. Application Data
(60) Provisional application No. 62/335,527, filed on May 12, 2016.

(51) Int. Cl. H01L 21/3213; H01J 37/32; H01L 21/67

(52) U.S. Cl. CPC H01L 21/32136; H01L 21/67069; H01J 37/32082; H01J 37/32449; H01J 2237/334

(57) ABSTRACT

Provided are methods and apparatuses for smoothly transitioning from a first plasma condition to a second plasma condition in a plasma processing chamber. An apparatus for plasma processing may be equipped with an RF power supply coupled to an impedance matching network to smoothly switch from a continuous wave (CW) plasma to a pulsing plasma, reversely, or in alternation without quenching the plasma. Or, the plasma processing chamber may be equipped to smoothly switch from a pulsing plasma at a first duty cycle to a pulsing mode at a second duty cycle without quenching the plasma. Such transitions may occur by ramping RF power, ramping duty cycle, and/or ramping pulsing frequency of the RF power supply being delivered to the plasma processing chamber so that impedance can be smoothly changed and matched by the impedance matching network during the transitions.

### CROSS-REFERENCE TO RELATED APPLICATIONS

This application claims the benefit of priority to U.S. Provisional Patent Application No. 62/335,527, filed May 12, 2016, and titled “METHODS OF CONTROL DURING TRANSITIONS BETWEEN CW AND PULSING PLASMAS,” which is incorporated by reference herein in its entirety and for all purposes.

### BACKGROUND

The present disclosure relates generally to plasma processing of a wafer, and more particularly to transitioning between plasmas where there's a significant change in electrical impedance, such as transitioning between continuous wave (CW) plasmas and pulsing plasmas without quenching the plasma.

Plasma processing can be used in a variety of operations in semiconductor processing, including etching, cleaning, treatment, and deposition. Radio-frequency (RF) power can be delivered to a plasma processing chamber, where the RF power can be delivered in a continuous wave (CW) mode or in a pulsing mode. This can result in two different types of plasma: (1) CW plasma or (2) pulsing plasma. Both CW plasmas and pulsing plasmas have been used in the semiconductor industry to achieve desired results.

In a CW mode, an RF power supply provides a continuous and constant amount of power to ignite or sustain a strong plasma, and such plasmas have been used in a variety of applications. RF power in the CW mode can be represented as sinusoidal waves having a certain frequency. The RF power supply can deliver power in the CW mode at any suitable frequency, which can be between about 200 KHz to about 200 MHz. Examples include 400 KHz, 2 MHz, 13.56 MHZ, 27 MHz, 60 MHz, 100 MHz, and 162 MHz.

In a pulsing mode, the RF power supply modulates the power delivered to the plasma processing chamber to ignite or sustain a plasma, and such plasmas have been used in many applications. RF power in the pulsing mode provide power in pulses over a given period of time “T.” Typically, such pulses can be in the form of a square waveform. A duty cycle can refer to the percentage of on time (Tₒₙ) during the total of on time and off time, where T=Tₒₙ+T_{off} in a given cycle. The RF power supply can deliver power in the pulsing mode at any suitable duty cycles, such as between about 1% to 99%. The RF power can deliver power in the pulsing mode at a pulsing frequency between about 10 Hz and about 100 kHz.

Plasmas generally include electrons, ions, radicals, and neutral species, all of which can have different residence times and lifetimes. For example, when RF power is turned off in a plasma processing chamber (e.g., during T_{off}), high energy electrons can rapidly leave the plasma while ions and radicals can remain longer in the plasma because of their lower diffusion velocities. This can influence various characteristics of the plasma (e.g., electric field potential, electron temperature, density of species, etc.), depending on the on time and off time of a pulse cycle of the plasma. Since the pulsing mode has a particular duty cycle and the CW mode essentially operates at 100% duty cycle, the nature of the plasma in a pulsing mode can be very different compared to the plasma in a CW mode. Using CW and pulsing modes can provide different kinds of plasma processing. Thus, a hybrid system using both CW and pulsing modes can provide extra benefits in processing a wafer in a plasma processing chamber.

It may be desirable to switch from CW to a desired pulsing condition, or reversely, or in alternation. In addition, it may be desirable to switch from one pulsing condition to another pulsing condition, where there is a significant difference in electrical impedance.

### SUMMARY

This disclosure pertains to a method of transitioning from a first plasma condition to a second plasma condition. The method includes igniting a plasma in a plasma processing chamber using an RF power supply coupled to an impedance matching network, where the RF power supply operates in a first mode to provide a first plasma condition having a first plasma impedance. The method further includes ramping, prior to the RF power supply operating in a second mode, one or more of the following: (1) an RF power of the RF power supply to a selected RF power, (2) a duty cycle of the RF power supply to a selected duty cycle, and (3) a pulsing frequency of the RF power supply to a selected pulsing frequency. The method further includes maintaining the plasma in the plasma processing chamber using the RF power supply operating in the second mode to provide a second plasma condition having a second plasma impedance, where the second plasma impedance is substantially different than the first plasma impedance.

In some implementations, the method further includes tuning an impedance of the plasma from the first mode to the second mode during ramping. In some implementations, the first mode is a continuous wave (CW) mode and the second mode is a pulsing mode. In some implementations, the first mode is a pulsing mode having a first duty cycle and the second mode is a pulsing mode having a second duty cycle, where the first duty cycle is different than the second duty cycle. In some implementations, the plasma is maintained in between the RF power supply operating in the first mode and the second mode without quenching the plasma. In some implementations, ramping one or more of the RF power, the duty cycle, and the pulsing frequency occurs in about one second or less. In some implementations, the impedance matching network includes one or more mechanically tunable elements, the one or more mechanically tunable elements simultaneously matching an impedance of the plasma during ramping. In some implementations, the method further includes etching tungsten on a wafer in the plasma processing chamber by exposing a wafer to the plasma, where the plasma is a nitrogen trifluoride or nitrogen plasma and the first mode is a continuous mode and the second mode is a pulsing mode.

The disclosure also pertains to an apparatus for transitioning from a first plasma condition to a second plasma condition. The apparatus includes a plasma processing chamber, an RF power supply coupled to the plasma processing chamber and configured to deliver power to the plasma processing chamber, an impedance matching network coupled to the RF power supply, and a controller. The controller is configured to provide instructions to perform the following operations: ignite a plasma in the plasma processing chamber using the RF power supply, where the RF power supply operates in a first mode to provide a first plasma condition having a first plasma impedance. The controller is further configured to ramp, prior to the RF power supply operating in a second mode, one or more of the following: (1) an RF power of the RF power supply, (2) a duty cycle of the RF power supply to a selected duty cycle, and (3) a pulsing frequency of the RF power supply to a selected pulsing frequency.

In some implementations, the controller is further configured to maintain the plasma in the plasma processing chamber using the RF power supply operating in the second mode to provide a second plasma condition having a second plasma impedance, where the second plasma impedance is substantially different than the first plasma impedance. In some implementations, the controller is further configured to tune an impedance of the plasma from the first mode to the second mode during ramping. In some implementations, the first mode is a CW mode and the second mode is a pulsing mode. In some implementations, an RF power is ramped prior to the RF power supply operating in the second mode, the RF power being ramped across a plurality of increasing or decreasing RF power levels, the RF power levels being between about 50 W and about 10000 W. In some implementations, a duty cycle is ramped prior to the RF power supply operating in the second mode, the duty cycle being ramped across a plurality of increasing or decreasing duty cycles, the duty cycles being between about 1% and about 99%. In some implementations, the impedance matching network includes one or more mechanically tunable elements, the one or more mechanically tunable elements simultaneously matching an impedance of the plasma during ramping.

These and other embodiments are described further below with reference to the figures.

### BRIEF DESCRIPTION OF THE DRAWINGS

FIG. 1A illustrates a graph showing a conventional transition from a CW mode to a pulsing mode.

FIG. 1B illustrates a graph showing a transition from a CW mode to a pulsing mode by gradually ramping down power.

FIG. 1C illustrates a graph showing a transition from a CW mode to a pulsing mode by gradually ramping down duty cycle.

FIG. 2 shows a flow diagram of an example process for transitioning plasma from a first plasma condition to a second plasma condition.

FIG. 3 illustrates a graph of measured power and tuning positions of RF match capacitors versus time for a conventional transition from a CW plasma to a pulsing plasma.

FIG. 4 illustrates a graph of measured power and tuning positions of RF match capacitors versus time for a transition from a CW plasma to a pulsing plasma by gradually ramping down duty cycle.

FIG. 5 illustrates a block diagram depicting an apparatus including a plasma processing chamber in accordance with disclosed implementations.

### DETAILED DESCRIPTION

### Introduction

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

Impedance matching is the practice of designing the input impedance of an electrical load or the output impedance of its corresponding signal source in order to maximize the power transfer and minimize reflection from the load. In general, impedance matching obtains a more efficient power transfer in a circuit. Typically, when an impedance of a source (Z_{source}) equals the impedance of a load (Z_{load}), maximum power transfer is obtained and minimum reflection occurs.

In a plasma processing context, impedance matching is used to minimize the reflected power back from a plasma discharge into the transmission line (e.g., RF cables), and maximize the power transferred from an RF generator into the plasma discharge. In addition, if the RF generator is not matched, we get reflected power that builds standing waves on a transmission line between the source (RF generator) and the load (plasma), which can lead to further power waste and cause frequency-dependent loss. An impedance matching network (also referred to as a “match unit”) is coupled to the RF generator and placed between the RF generator and the plasma processing chamber. The impedance matching network can transform the load impedance presented from the plasma discharge to match the source impedance of the RF generator. Otherwise, a significant amount of power from the RF generator does not reach the plasma discharge due to the reflected power.

Load impedance from the plasma, or plasma impedance, can correspond to its plasma characteristics. One of the characteristics of plasma is its density. Accordingly, as plasma characteristics change, so does the plasma impedance. Therefore, the impedance matching network necessarily adjusts with changes in plasma characteristics to facilitate impedance matching. In some implementations, an impedance matching network includes mechanically tunable elements, such as capacitors and/or inductors, to couple RF energy to plasma. A system controller can monitor the reflected power from the impedance matching network, and the system controller can tune the capacitance or inductance of the impedance matching network to achieve a more sufficient match. However, this tuning process via the impedance matching network may be slow.

CW plasmas and pulsing plasmas present different plasma characteristics, thereby providing different plasma impedances. For example, CW plasmas may contain electrons, ions, radicals, and neutral species in the plasma discharge, and pulsing plasmas may have different plasma densities and electron temperature, and thus different radical species and densities. When the plasma characteristics change, the impedance matching network must mechanically respond to match impedance.

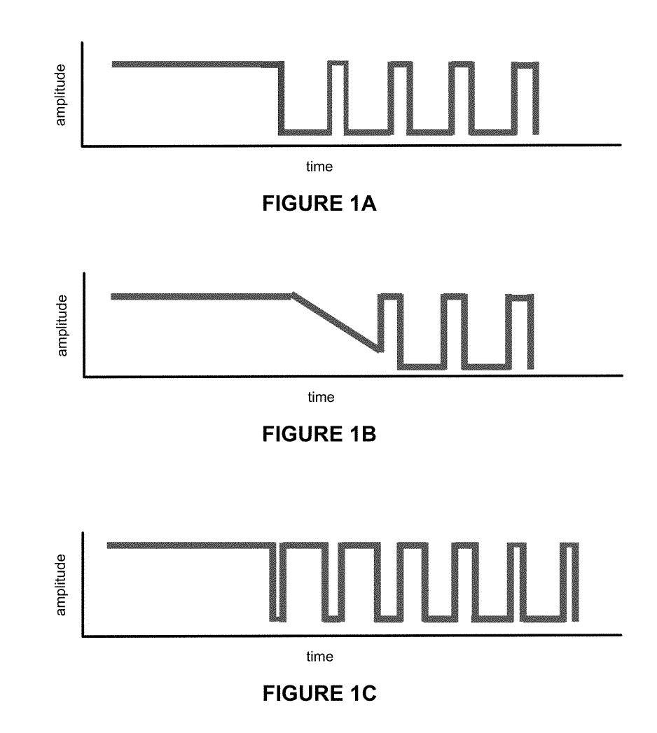

FIG. 1A illustrates a graph showing a conventional transition from a CW mode to a pulsing mode. The amplitude corresponds to the output power being delivered from the RF power supply or RF generator. The CW mode in FIG. 1A shows a constant amplitude while the pulsing mode shows a series of pulses over time. In FIG. 1A, the RF power supply delivers power in the CW mode in one operation followed by the RF power supply delivering power in a pulsing mode in a subsequent operation. During the transition between the CW mode and the pulsing mode, the plasma impedance values can dramatically change.

When the RF power supply ignites a plasma in a CW mode for a given power and pressure, the impedance matching network can tune to match the impedance from the plasma in the plasma processing chamber. When the RF power supply switches to a pulsing mode, the power reflected back to the RF power supply can be substantially large. The impedance matching network can be unable to quickly match impedance between the source (RF generator) and the load (plasma), so the RF power supply can drop its output power substantially. This often results in quenching or extinguishing of the plasma. This impedance matching network stops tuning while the output power of the RF power supply has dropped and the plasma is quenched. Then the pulsing mode is turned on to re-ignite the plasma, but only after one or more seconds has passed and only after the plasma is quenched.

By way of example, the impedance matching network can include a variable capacitor and a step motor. The step motor can mechanically tune the capacitance of the variable capacitor, and effectively tune the impedance for impedance matching. However, the duration of time during a transition between a CW mode and a pulsing mode can be more than one second. If a process recipe calls for 20 seconds of operation in the CW mode and 40 seconds of operation in the pulsing mode, the transition time for quenching and re-igniting the plasma to allow for impedance matching may still be acceptable. However, for process recipes that are shorter in duration, this amount of time may be unacceptably slow in a number of plasma processing applications. For example, if the process recipe calls for less than 10 seconds of operation in the CW plasma mode and less than 10 seconds of operation in the pulsing plasma mode, the transition time for quenching and re-igniting the plasma to allow for impedance matching may not be acceptable. This can be useful in a variety of applications, including but not limited to plasma etching, chemical vapor deposition (CVD), plasma-aided ion implantation, atomic layer epitaxy (ALE), and atomic layer deposition (ALD). It will be understood that other applications may apply.

In some implementations, a hybrid of CW mode and pulsing mode can be used in a plasma etching operation. By way of an example, a nitrogen trifluoride (NF₃) or nitrogen (N₂) plasma can be generated to etch tungsten (W). An RF generator in a CW mode can generate a strong plasma to uniformly and efficiently etch W. The RF generator can switch to a pulsing mode towards the end of the operation to generate a plasma with lower electron energies and, thus, lower concentration of nitrogen radicals. The electron energies and concentration of nitrogen radicals can depend on the pulsing conditions of the pulsing mode. In some implementations, it may be possible to pulse RF plasma at varying conditions of power, pulse length, and/or duty cycle. The ratio of fluorine and nitrogen radicals can be modulated accordingly. When the concentration of nitrogen radicals is lowered during the pulsing mode, this can mitigate the effects of nitridation on the wafer surface. Nitridation of tungsten can form tungsten nitride, which can lead to post-etch incubation delay of subsequent tungsten growth and cause gapfill issues.

However, this hybrid of CW mode and pulsing mode will most likely run without a smooth transition in between, potentially quenching the plasma. This means that such a hybrid operation will likely require additional plasma ignition for the subsequent pulsing mode, which may be undesired for processes involving very short and precise plasma on time. This hybrid of CW mode and pulsing mode will also likely cause repeatability and tool-to-tool matching issues. In other words, the following factors contribute to the repeatability and tool-to-tool matching issues: the timing of the quenching, the timing of the re-ignition, and the timing for re-stabilization after re-ignition during which there is high reflected power. All these differences can be sensitive to the chamber conditions and RF hardware. Moreover, the CW mode may be performed in one chamber and the pulsing mode may be performed in a separate chamber, which can further exacerbate delays. Therefore, such a hybrid of CW mode and pulsing mode may produce inconsistent results in processing.

The present disclosure relates to a method for smoothly transitioning from a first plasma condition to a second plasma condition in a plasma processing chamber. The method can be performed in an integrated process tool that allows for a hybrid of CW mode and pulsing mode to generate and sustain a plasma without quenching the plasma, or of a first pulsing mode at a first duty cycle and a second pulsing mode at a second duty cycle to generate and sustain a plasma without quenching the plasma. The integrated process tool can allow for switching between two different plasma conditions with minimal down time, which can be important in processes that involve very short and precise plasma on time. This can lead to faster transitions, integrated processes to eliminate tool-to-tool matching issues, and more repeatable and consistent results.

Switching from the first plasma condition to the second plasma condition may be accompanied by a significant change in plasma impedances between the first plasma condition and the second plasma condition. In some implementations, the change in plasma impedances can be substantial. For example, the positions of the tuning capacitors responding to the difference in plasma impedances can be varied by equal to or greater than about 50%, equal to or greater than about 60%, equal to or greater than about 70%, or equal to or greater than about 80%. In addition or in the alternative, the difference in plasma impedances can be varied by several or more volts in a 0-10 V range, such as equal to or greater than 3 V in a 0-10 V range, such as equal to or greater than 4 V in a 0-10 V range, or such as equal to or greater than 5 V in a 0-10 V range. The positions in the tuning can correspond to the difference in plasma impedance. If the difference is too small, then frequency tuning can be utilized to the RF power supply can quickly match impedance. However, if the difference is too large, then frequency tuning may not be practical. Moreover, the response of the impedance matching network typically takes too long and can result in potentially quenching the plasma during transitions between the first plasma condition and the second plasma condition. The present disclosure allows the impedance matching network coupled to an RF power supply to match the plasma impedance of the second plasma condition in a fast time and without quenching the plasma. In some implementations, the transition between the first plasma condition to the second plasma condition can be equal to or less than about 2 seconds, equal to or less than about 1 second, or equal to or less than about 100 milliseconds. In some implementations, this smoother and faster impedance matching without quenching the plasma be done by (1) changing the RF power in the duration between the first and the second plasma conditions, or by (2) changing the duty cycle in the duration between the first and the second plasma conditions.

FIG. 1B illustrates a graph showing a transition from a CW mode to a pulsing mode by gradually ramping down RF power. As shown in FIG. 1B, the RF power can be gradually reduced or ramped down in the transition between the CW mode to the pulsing mode. When the RF power is brought down to a level where the impedance is matched for the second plasma condition, then the RF power supply can switch to a pulsing mode. That way, the RF power is gradually changed so as to guide the impedance matching network to match the plasma impedance for the pulsing mode that is desired.

Ramped as used herein is defined as changing the conditions incrementally during exposure to plasma. In some implementations, ramping RF power can mean incrementally increasing or decreasing RF power from a first selected RF power to a second selected RF power during exposure to plasma. For example, ramping RF power can mean having three or more intermediate RF powers when increasing or decreasing RF power from a first selected RF power to a second selected RF power. In some implementations, the selected RF power can be between about 0 W and about 20000 W, or between about 50 W and about 10000 W. The RF power can be ramped so that the impedance matching network is guided to match the plasma impedance from the first plasma condition to the second plasma condition. In FIG. 1B, for example, the RF power can be ramped down so that the impedance matching network is guided to match the plasma impedance from the CW mode to the pulsing mode. If the RF power is 900 W in the CW mode, then the RF power can be ramped down to 300 W prior to switching the RF power supply to the pulsing mode. In some implementations, the RF power can be ramped from a first selected RF power to a second selected RF power in less than about 1 second and without quenching the plasma. Once the transition is made to the second plasma condition, the RF power may be maintained at the same RF power, whether in a pulsing mode or CW mode. The power source in the present disclosure is not limited to only RF power supply, but may equally apply to DC power supply as well. For example, the same disclosed method can be applied in scenarios where plasma is changed from a DC CW plasma to a DC pulsing plasma.

FIG. 1C illustrates a graph showing a transition from a CW mode to a pulsing mode by gradually ramping down duty cycle. As shown in FIG. 1C, the duty cycle can be gradually reduced or ramped down in the transition between the CW mode and the pulsing mode. The pulsing mode can have a duty cycle between about 1% and about 99%. When ramping the duty cycle, the sequence can start with CW mode, then changing to a pulsing mode but at the highest duty cycle possible (e.g., 99%, 95%, or 90% based on the RF power supply capability), and then incrementally reducing from the highest duty cycle to a desired duty cycle. Incrementally reducing can mean having three or more intermediate duty cycles before reaching a desired duty cycle. That way, the duty cycle is gradually changed so as to guide the impedance matching network to match the plasma impedance for the pulsing mode that is desired.

In some implementations, ramping duty cycle can mean incrementally increasing or decreasing duty cycle from a first selected duty cycle to a second selected duty cycle during exposure to plasma. If the CW mode is essentially treated as plasma with 100% duty cycle, then the duty cycle can ramped from 100% to a lower duty cycle. For example, if the lower selected duty cycle is 25% duty cycle, the duty cycle can be ramped from CW mode (100% duty cycle) to a pulsing plasma at 90% duty cycle, to 80% duty cycle, to 60% duty cycle, to 40% duty cycle, and ultimately to 25% duty cycle. Or, the duty cycle can be ramped from CW mode (100% duty cycle) to a pulsing plasma at 95% duty cycle, to 90% duty cycle, to 85% duty cycle, to 80% duty cycle, and ultimately to 25% duty cycle. There could be a number of different gradually varying set points, and the gradually varying set points can be programmed. What happens is that there is a plurality of increasing or decreasing duty cycles between the first selected duty cycle and the second selected duty cycle. The same can be said of ramping power in FIG. 1B. In FIG. 1C, there are a plurality of decreasing duty cycles from CW mode (100% duty cycle) to the pulsing mode that is about 25% duty cycle. That way, the impedance matching network is guided to match the plasma impedance from the CW mode to the pulsing mode at 25% duty cycle. In some implementations, the duty cycle can be ramped from a first selected duty cycle to a second selected duty cycle in less than about 1 second and without quenching the plasma.

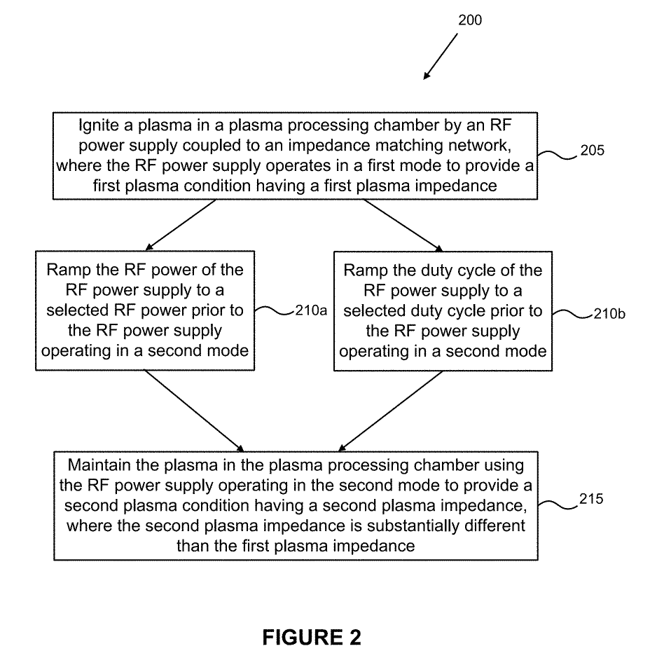

FIG. 2 shows a flow diagram of an example process for transitioning plasma from a first plasma condition to a second plasma condition. Each plasma condition can represent the conditions of the plasma, including the RF power of the RF power supply, the duty cycle operated by the RF power supply, the plasma impedance of the plasma, and the frequency of the RF power supply, among other conditions. The second plasma condition has a plasma impedance that is substantially different from the first plasma condition. In some implementations, the second plasma condition has a plasma impedance that is different from the first plasma condition by an amount equal to or greater than about 50%.

At block 205 of a process 200, a plasma is ignited in a plasma processing chamber by an RF power supply coupled to an impedance matching network, where the RF power supply operates in a first mode to provide a first plasma condition having a first plasma impedance. In some implementations, the first mode can be a CW mode or a pulsing mode at a selected duty cycle. The RF power supply can operate in the first mode at a selected RF power and at a selected frequency. In some implementations, the RF power can be between about 50 W and about 10000 W, and the selected frequency can be between about 2 Hz and about 100 MHz, such as between about 1 MHz and about 100 MHz for a high frequency RF generator and about 2 Hz and about 100 kHz for a low frequency RF generator.

The source for generation of plasma can be any suitable plasma source in the plasma processing chamber. In some implementations, the source can be an inductively-coupled plasma (ICP) source. In some implementations, the source can be a transformer-coupled plasma (TCP) source. In some implementations, the source can be a capacitively-coupled plasma (CCP) source. In some implementations, the source can be a DC plasma source. In some other implementations, the source can be an RF plasma source. It will be understood that other sources for plasma generation may be applicable.

In some implementations, the impedance matching network can be coupled to the RF power supply and can include one or more mechanically tunable elements, such as capacitors and/or inductors. The one or more mechanically tunable elements may be manually or automatically tuned to match the impedance of the plasma impedance. In some implementations, the impedance matching networks can include one or more measurement devices used to determine the effectiveness of the impedance matching network to match to the plasma. For example, the one or more measurement devices can measure reflected power, so that the one or more mechanically tunable elements can be tuned to minimize reflected power to the RF power supply. In some implementations, the impedance matching networks can be a commercially available impedance matching network, such as models from COMET Technologies USA, Inc. of San Jose, Calif.

The RF power supply can be an RF generator that can operate in a CW mode or pulsing mode. In some implementations, the RF power supply may be configured for fast frequency tuning. For example, the RF power supply may be able to vary frequency within about +/−5% in response to a sensed reflected power measurement in order to minimize reflected power. Such frequency tuning may occur quickly in about 100 milliseconds or less to minimize reflected power from a plasma. While fast frequency tuning in the RF power supply may be capable of tuning to different plasma impedance values, it may not be able to tune across large differences in plasma impedance values. Thus, the window of plasma impedance values covered by frequency tuning may be insufficiently small.

One or more gas species may be delivered into the plasma processing chamber for processing a wafer. The RF power supply may activate the one or more gas species to ignite the plasma. In some implementations, the one or more gas species can include NF₃ or N₂ for plasma etching. For example, the NF₃ or N₂ plasma can be used for etching W, as discussed above. In some implementations, the one or more gas species may include gas species for ALE and ALE, because ALE and ALD processes may require short time windows that the process 200 can take advantage of. The process 200 may be applied in a manner not limited to etching, ALD, and ALE processes, but may also be applied to CVD processes, and plasma-aided ion implantation processes, among other possible applications.

At block 210a of the process 200, the RF power of the RF power supply is ramped to a selected RF power prior to the RF power supply operating in a second mode. At block 210b of the process 200, the duty cycle of the RF power supply is ramped to a selected duty cycle prior to the RF power supply operating in a second mode. In addition or in the alternative, a pulsing frequency of the RF power supply can be ramped to a selected pulsing frequency prior to the RF power supply operating in a second mode. The pulsing frequency can relate to the number of pulses per unit time. In some implementations, the pulsing frequency can be ramped anywhere between about 10 Hz and about 200 kHz. In one example, the pulsing frequency can be ramped to a selected pulsing frequency prior to the RF power supply operating in the second mode without changing the RF power or duty cycle. In another example, the pulsing frequency can be ramped to a selected pulsing frequency and the RF power can be ramped to a selected RF power prior to the RF power supply operating in the second mode. In another example, the pulsing frequency can be ramped to a selected pulsing frequency and the duty cycle can be ramped to a selected duty cycle prior to the RF power supply operating in the second mode.

With respect to block 210a, the RF power may be ramped across a plurality of increasing or decreasing RF powers before reaching the selected RF power. In other words, the RF power may be gradually increased or gradually decreased before reaching the selected RF power. That way, the impedance of the plasma can be changed smoothly instead of drastically, and the impedance matching network can be simultaneously tuned to match the impedance of the plasma. In some implementations, the impedance matching network can follow the change in the impedance of the plasma at a maximum speed mechanically possible. This can achieve minimum transition time with repeatable results, thereby minimizing chamber matching issues.

With respect to block 210b, the duty cycle of the RF power supply may be ramped across a plurality of increasing or decreasing duty cycles before reaching the selected duty cycle. In other words, the duty cycle may be gradually increased or gradually decreased before reaching the selected duty cycle. That way, the impedance of the plasma can be changed smoothly instead of drastically, and the impedance matching network can be simultaneously tuned to match the impedance of the plasma. In some implementations, the impedance matching network can follow the change in the impedance of the plasma at a maximum speed mechanically possible.

In addition or in the alternative to the duty cycle or RF power, the pulsing frequency can be gradually increased or gradually decreased before reaching a selected pulsing frequency, which can also facilitate smooth changes in the impedance of the plasma for the impedance matching network to follow.

Ramping the RF power, duty cycle, and/or pulsing frequency can be accomplished manually or automatically. In some implementations, a tool software program can send a series of commands of gradually increasing or decreasing set points to the RF power supply. In some implementations, a special interface/communication between the RF power supply and the tool software program can be provided. For example, a digital communication (e.g., EtherNet, EtherCAT, or Serial) can be provided for the tool software program so that pulsing parameters and transition parameters can be sent to the RF power supply to execute in a timely manner. In some implementations, a hybrid mode of communication with both digital and analog interfaces may be required for fast On/Off switching.

In some implementations for ramping the RF power, duty cycle, and/or pulsing frequency automatically, instructions may be included in the RF generator functions, such as in firmware. That way, pulsing parameters such as duty cycle can be smoothly ramped within a pre-configured duration.

At block 215 of the process 200, the plasma is maintained in the plasma processing chamber using RF power supply operating in the second mode to provide a second plasma condition having a second plasma impedance, where the second plasma impedance is substantially different than the first plasma impedance. What is substantially different can correspond to positions of the mechanically tunable elements (e.g., capacitors), where the positions can vary by at least 50%. For example, in an RF match electrical design, the position of a first tuning capacitor can be at 6 V out of 10 V for the first plasma condition and the position of the second tuning capacitor can be at 3 V out of 10 V for the second plasma condition. The difference in plasma impedance can correlate to the capacitor tuning position. Any difference equal to or greater than about 2 V in a 0-10 V range can constitute a substantial difference, as such a difference can potentially quench the plasma or at least severely cause matching tuning overshoot to lead to poor repeatability.

As the RF power or the duty cycle is ramped, the impedance matching network is tuned to match the impedance of the second plasma impedance from the second mode. The RF power supply transitions from the first mode to the second mode without quenching the plasma so that the plasma does not need to be re-ignited. In some implementations, the transition between the first mode and the second mode can occur in two seconds or less, in one second or less, or in 100 milliseconds or less.

In some implementations, the first mode can be a CW mode and the second mode can be a pulsing mode, or vice versa, where the pulsing mode can have a duty cycle between about 1% and about 99%. In some implementations, the first mode can be a pulsing mode at a first duty cycle and the second mode can be a pulsing mode at a second duty cycle, where the first duty cycle is different than the second duty cycle. The process 200 may accomplish the transition from the first mode to the second mode smoothly and quickly, meaning that there is minimal transition time and that the plasma is not quenched and subsequently re-ignited.

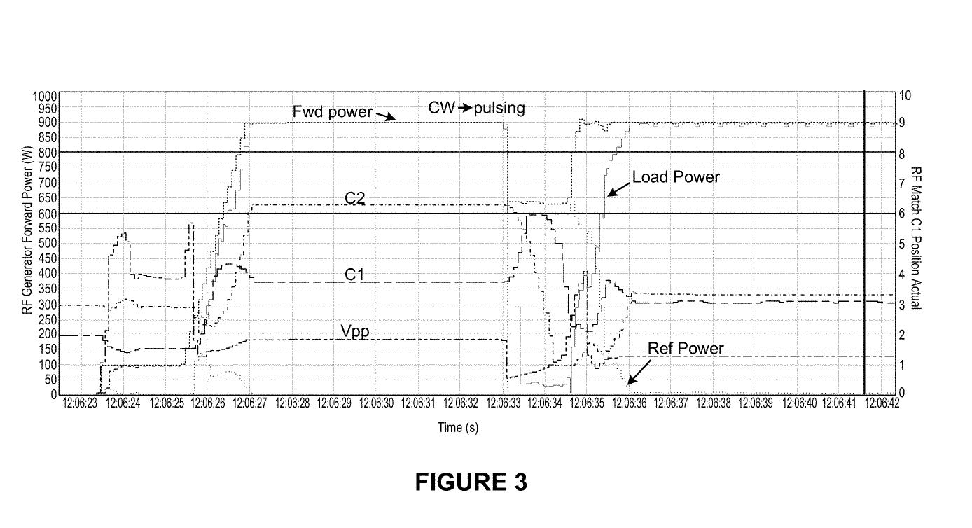

FIG. 3 illustrates a graph of measured power and tuning positions of RF match capacitors versus time for a conventional transition from a CW mode to a pulsing mode. Forward power is the amount of RF power that the RF generator is producing and trying to send to the plasma. The reflected power is the amount of power that is “bounced back” from the plasma. Load power is the amount of power that is actually delivered to the plasma. Reflected power results when the plasma impedance is not matched with the source impedance. Power is illustrated on the y-axis ranging from 0 W to 1000 W, and time is illustrated on the x-axis ranging across about 20 seconds.

As shown in FIG. 3, an impedance matching network can include two capacitors C1 and C2 as mechanically tunable elements. When the RF generator switches from a CW mode to a pulsing mode at around the 33-second mark, the load power significantly drops almost to zero power. At around the same time, the reflected power spikes. To minimize the reflected power, the capacitors C1 and C2 fluctuate until they eventually stabilize to match the impedance of the plasma in the pulsing mode. However, this process can take over one second, and can potentially quench the plasma and require re-ignition of the plasma.

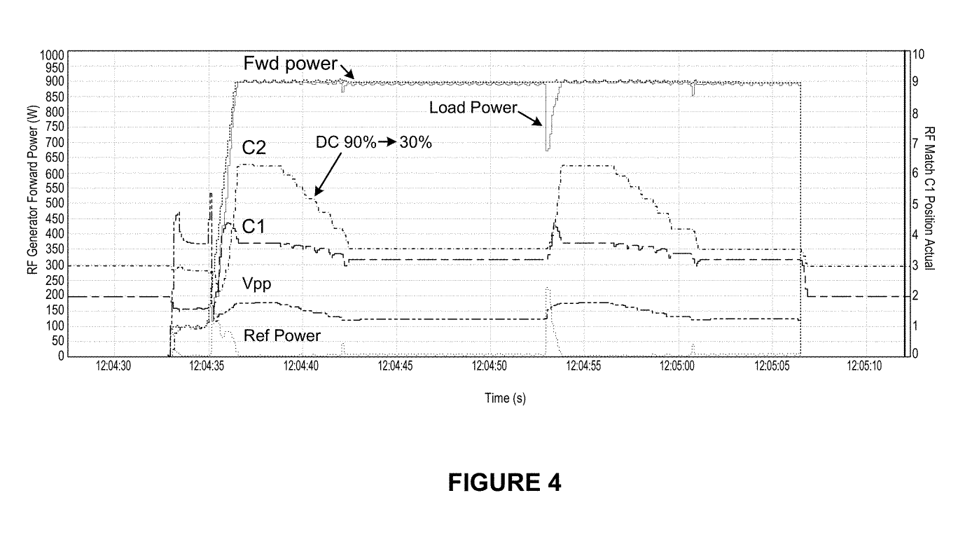

FIG. 4 illustrates a graph of measured power and tuning positions of RF match capacitors versus time for a transition from a CW mode to a pulsing mode by gradually ramping down duty cycle. Power is illustrated on the y-axis ranging from 0 W to 1000 W, and time is illustrated on the x-axis ranging across over 40 seconds. As shown in FIG. 4, the RF generator gradually ramps down the duty cycle from 90% duty cycle to 30% duty cycle. Each step can change by 10% or less. In doing so, the load power does not significantly drop and the reflected power does not spike as in FIG. 3. In fact, reflected power remains low as the duty cycle is ramped down. The forward power remains relatively constant. In FIG. 4, the transition between the CW mode and the pulsing mode can occur smoothly and quickly by allowing for match tuning to occur smoothly and quickly. The match tuning between C1 and C2 in FIG. 4 can occur relatively smoothly and quickly without causing a spike in reflected power.

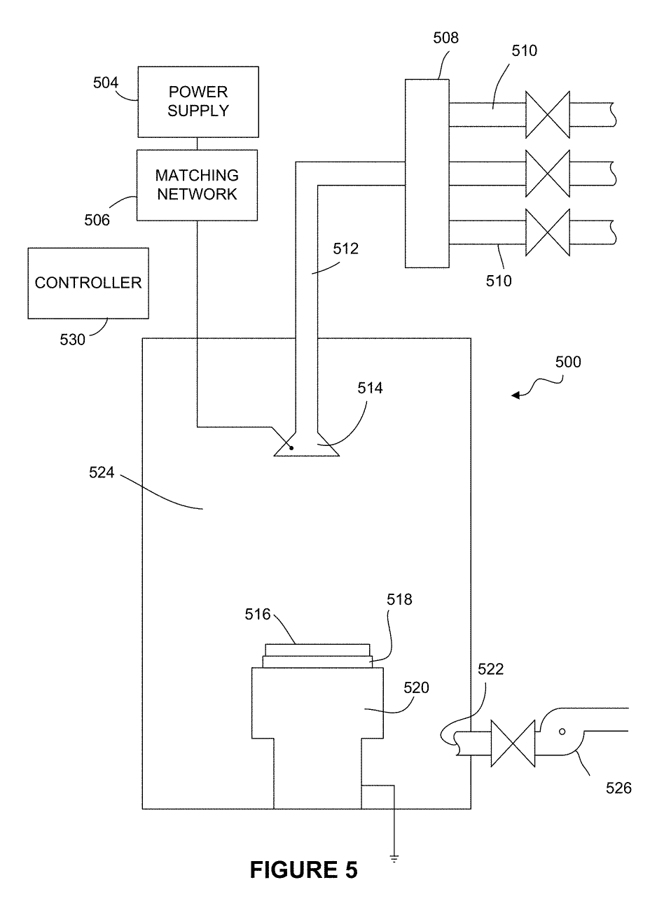

FIG. 5 illustrates a simple block diagram depicting various reactor components arranged for implementing methods described herein. As shown, an apparatus 500 includes a plasma processing chamber 524 that encloses various components of the apparatus 500 and serves to contain a plasma generated by a capacitive-discharge type system including a showerhead 514 working in conjunction with a grounded block 520. An RF power supply 504 may be connected to a matching network 506 and to the showerhead 514. In some implementations, the RF power supply 504 includes a high frequency (HF) radio frequency (RF) generator and a low frequency (LF) RF generator so that the RF power supply 504 can control high- and low-frequency power sources independently of one another. The power and frequency supplied by matching network 506 may be sufficient to generate a plasma from process gases supplied to the plasma processing chamber 524. For example, the matching network 506 may provide 50 W to 10000 W of power. In some implementations, the HFRF component of the RF power supply 504 may generally have a frequency between 1 MHz to 100 MHz, e.g., 13.56 MHz. In some implementations, the LFRF component of the RF power supply 504 may generally have a frequency less than about 1 MHz, e.g., 100 kHz. The plasma power may be intermittently pulsed in a pulsing plasma or may be continuously powered in a continuous wave plasma. In some implementations, plasma strikes may last on the order of milliseconds or seconds. Short plasma strikes may require quick stabilization of the plasma, which may thereby require quick impedance matching from the matching network 506.

Within the plasma processing chamber 524, a pedestal 518 may support a substrate 516. The pedestal 518 may include a chuck, a fork, or lift pins (not shown) to hold and transfer the substrate during and between the deposition and/or plasma treatment reactions. The chuck may be an electrostatic chuck, a mechanical chuck, or various other types of chuck as are available for use in the industry and/or for research.

Various process gases may be introduced via inlet 512. Multiple source gas lines 510 are connected to manifold 508. The gases may be premixed or not. Appropriate valving and mass flow control mechanisms may be employed to ensure that the correct process gases are delivered during the deposition and plasma treatment phases of the process. In the case where a chemical precursor(s) is delivered in liquid form, liquid flow control mechanisms may be employed. Such liquids may then be vaporized and mixed with process gases during transportation in a manifold heated above the vaporization point of the chemical precursor supplied in liquid form before reaching the deposition chamber.

Process gases may exit the plasma processing chamber 524 via an outlet 522. A vacuum pump, e.g., a one or two stage mechanical dry pump and/or turbomolecular pump 526, may be used to draw process gases out of the plasma processing chamber 524 and to maintain a suitably low pressure within the plasma processing chamber 524 by using a closed-loop-controlled flow restriction device, such as a throttle valve or a pendulum valve.

In some implementations, an apparatus 500 may be provided that is configured to perform the techniques described herein. A suitable apparatus may include hardware for performing various process operations as well as a controller 530 having instructions for controlling process operations in accordance with the disclosed embodiments. The controller 530 will typically include one or more memory devices and one or more processors communicatively connected with various process control equipment, e.g., valves, RF generators, substrate handling systems, etc., and configured to execute the instructions so that the apparatus 500 will perform a technique in accordance with the disclosed embodiments, e.g., a technique such as that provided in the operations of FIG. 2. Machine-readable media containing instructions for controlling process operations in accordance with the present disclosure may be coupled to the controller 530. The controller 530 may be communicatively connected with various hardware devices, e.g., mass flow controllers, valves, RF power supplies, vacuum pumps, etc. to facilitate control of the various process parameters that are associated with the deposition operations as described herein.

In some implementations, the controller 530 may control all of the activities of the apparatus 500. The controller 530 may execute system control software stored in a mass storage device, loaded into a memory device, and executed on a processor. The system control software may include instructions for controlling the timing of gas flows, substrate movement, RF generator activation, RF power levels, duty cycle, pulsing frequency, etc., as well as instructions for controlling the mixture of gases, the chamber and/or station pressure, the chamber and/or station temperature, the substrate temperature, the target power levels, the substrate pedestal, chuck, and/or susceptor position, and other parameters of a particular process performed by the apparatus 500. For example, various process tool component subroutines or control objects may be written to control operation of the process tool components necessary to carry out various process tool processes. The system control software may be coded in any suitable computer readable programming language.

The controller 530 may typically include one or more memory devices and one or more processors configured to execute the instructions so that the apparatus will perform a technique in accordance with the present disclosure. Machine-readable media containing instructions for controlling process operations in accordance with disclosed embodiments may be coupled to the controller 530.

An apparatus may include a plasma processing chamber, an RF power supply coupled to the plasma processing chamber and configured to deliver power to the plasma processing chamber, an impedance matching network coupled to the RF power supply, and a controller. The controller may be configured to provide instructions for performing operations, including the operations described in the process 200 of FIG. 2. The controller may be part of a system, which may be part of the apparatus, such as an apparatus 500 of FIG. 5. Such systems can comprise semiconductor processing equipment, including a processing tool or tools, chamber or chambers, a platform or platforms for processing, and/or specific processing components (a wafer support, a gas flow system, etc.). These systems may be integrated with electronics for controlling their operation before, during, and after processing of the wafer. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, RF generator settings, impedance matching network settings, frequency settings, flow rate settings, fluid delivery settings, positional and operation settings, wafer transfers into and out of a tool and other transfer tools and/or load locks connected to or interfaced with a specific system.

The controller may provide program instructions for implementing the above-described processes. The program instructions may control a variety of process parameters, such as RF power level, duty cycle, and pulsing frequency. For example, the controller may include instructions for ramping the RF power, ramping the duty cycle, and/or ramping the pulsing frequency during a transition between a first mode and a second mode. When ramping to a selected RF power, duty cycle, and/or pulsing frequency, the program instructions may include various set points to execute within a certain time frame to reach the selected RF power, duty cycle, and/or pulsing frequency.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller may communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Lithographic Patterning

The apparatuses/processes described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### OTHER EMBODIMENTS

Although illustrative embodiments and applications of this invention are shown and described herein, many variations and modifications are possible which remain within the concept, scope, and spirit of the invention, and these variations would become clear to those of ordinary skill in the art after perusal of this application. Accordingly, the present embodiments are to be considered as illustrative and not restrictive, and the invention is not to be limited to the details given herein, but may be modified within the scope and equivalents of the appended claims.

What is claimed is:

1. A method of transitioning from a first plasma condition to a second plasma condition, the method comprising:
igniting a plasma in a plasma processing chamber using an RF power supply coupled to an impedance matching network, wherein the RF power supply operates in a first mode to provide a first plasma condition having a first plasma impedance;
ramping, prior to the RF power supply operating in a second mode, one or more of the following: (1) an RF power of the RF power supply to a selected RF power, (2) a duty cycle of the RF power supply to a selected duty cycle, and (3) a pulsing frequency of the RF power supply to a selected pulsing frequency; and
maintaining the plasma in the plasma processing chamber using the RF power supply operating in the second mode to provide a second plasma condition having a second plasma impedance, wherein the second plasma impedance is substantially different than the first plasma impedance.

2. The method of claim 1, further comprising:
tuning an impedance of the plasma from the first mode to the second mode during ramping.

3. The method of claim 1, wherein the first mode is a continuous wave (C ode and the second mode is a pulsing mode.

4. The method of claim 1, wherein the first mode is a pulsing mode having a first duty cycle and the second mode is a pulsing mode having a second duty cycle, wherein the first duty cycle is different than the second duty cycle.

5. The method of claim 1, wherein the plasma is maintained in between the RF power supply operating in the first mode and the second mode without quenching the plasma.

6. The method of claim 1, wherein ramping one of more of the RF power, the duty cycle, and the pulsing frequency occurs in about one second or less.

7. The method of claim 1, wherein an RF power is ramped prior to the RF power supply operating in the second mode.

8. The method of claim 7, wherein ramping the RF power comprises ramping the RF power across a plurality of increasing or decreasing RF power levels, the RF power levels being between about 50 W and about 10000 W.

9. The method of claim 1, wherein a duty cycle is ramped prior to the RF power supply operating in the second mode.

10. The method of claim 9, wherein ramping the duty cycle comprises ramping the duty cycle across a plurality of increasing or decreasing duty cycles, the duty cycles being between about 1% and about 99%.

11. The method of claim 1, wherein the impedance matching network includes one or more mechanically tunable elements, the one or more mechanically tunable elements simultaneously matching an impedance of the plasma during ramping.

12. The method of claim 1, further comprising
etching tungsten (W) on a wafer in the plasma processing chamber by exposing a wafer to the plasma, wherein the plasma is an nitrogen trifluoride (NF₃) or nitrogen (N₂) plasma and the first mode is a continuous mode and the second mode is a pulsing mode.

13. An apparatus for transitioning from a first plasma condition to a second plasma condition, the apparatus comprising:
a plasma processing chamber;
an RF power supply coupled to the plasma processing chamber and configured to deliver power to the plasma processing chamber;
an impedance matching network coupled to the RF power supply; and
a controller configured to provide instructions to perform the following instructions:
ignite a plasma in the plasma processing chamber using the RF power supply, wherein the RF power supply operates in a first mode to provide a first plasma condition having a first plasma impedance; and
ramp, prior to the RF power supply operating in a second mode, one or more of the following: (1) an RF power of the RF power supply to a selected RF power, (2) a duty cycle of the RF power supply to a selected duty cycle, and (3) a pulsing frequency of the RF power supply to a selected pulsing frequency.

14. The apparatus of claim 13, wherein the controller is further configured to:
maintain the plasma in the plasma processing chamber using the RF power supply operating in the second mode to provide a second plasma condition having a second plasma impedance, wherein the second plasma impedance is substantially different than the first plasma impedance.

15. The apparatus of claim 13, wherein the controller is further configured to:
tune an impedance of the plasma from the first mode to the second mode during ramping.

16. The apparatus of claim 13, wherein the first s a continuous wave (CW) mode and the second mode is a pulsing mode.

17. The apparatus of claim 13, wherein the first mode is a pulsing mode having a first duty cycle and the second mode is a pulsing mode having a second duty cycle, wherein the first duty cycle is different than the second duty cycle.

18. The apparatus of claim 13, wherein an RF power is ramped prior to the RF power supply operating in the second mode, the RF power being ramped across a plurality of increasing or decreasing RF power levels, the RF power levels being between about 50 W and about 10000 W.

19. The apparatus of claim 13, where a duty cycle is ramped prior to the RF power supply operating in the second mode, the duty cycle being ramped across a plurality of increasing or decreasing duty cycles, the duty cycles being between about 1% and about 99%.

20. The apparatus of claim 13, wherein the impedance matching network includes one or more mechanically tunable elements, the one or more mechanically tunable elements simultaneously matching an impedance of the plasma during ramping.
